(19) United States
(12) Patent Application Publication
(10) Pub. No.: US 2015/0091572 A1
(43) Pub. Date: Apr. 2, 2015

(54) METHOD AND MAGNETIC RESONANCE APPARATUS TO ACQUIRE RAW DATA FOR IMAGE CONSTRUCTION WITH MULTIPLE VIRTUAL COILS

(71) Applicant: SIEMENS AKTIENGESELLSCHAFT, Munchen (DE)

(72) Inventors: Patrick GROSS, Ismaning (DE); Rene GUMBRECHT, Herzogenaurach (DE)

(73) Assignee: SIEMENS AKTIENGESELLSCHAFT, Munchen (DE)

(21) Appl. No.: 14/504,818

(22) Filed: Oct. 2, 2014

(30) Foreign Application Priority Data
Oct. 2, 2013 (DE) 102013220010.2

(51) Int. Cl. G01R 33/561; G01R 33/48; G01R 33/36; G01R 33/56

(52) U.S. Cl. CPC G01R 33/5615; G01R 33/5608; G01R 33/4822; G01R 33/36
USPC 324/309; 324/318

(57) ABSTRACT

In a method to acquire magnetic resonance (MR) signals as gradient echoes, a first RF pulse is radiated and multiple bipolar magnetic field gradients are switched to generate multiple first gradient echoes at different echo times after radiation of the first RF pulse, and the multiple first gradient echoes are acquired in multiple raw data sets, in each of which a first line is filled with MR signals, and chronologically adjacent gradient echoes that occur after radiation of the first RF pulse are acquired with magnetic field gradients with opposite polarity. A second RF pulse is radiated and multiple bipolar magnetic fields are switched to generate multiple second gradient echoes after radiation of the second RF pulse. The multiple second gradient echoes are acquired in the multiple raw data sets, and in each raw data set, a second line, adjacent the first line, of the associated raw data set is filled with MR signals, wherein chronologically adjacent gradient echoes that occur after radiation of the second RF pulse are acquired with magnetic field gradients with opposite polarity. The multiple bipolar magnetic field gradients for generation of the first and second gradient echoes are switched such that, in each of the raw data sets, the first line of the associated raw data set and the adjacent second line are filled with MR signals in opposite directions.

### BACKGROUND OF THE INVENTION

1. Field of the Invention

The present invention concerns a method to acquire magnetic resonance (MR) signals, wherein the MR signals are gradient echoes.

2. Description of the Prior Art

In the acquisition of multiple MR images that each have a characteristic echo time TE, it is advantageous for the signal-to-noise ratio to use a single RF signal excitation and to subsequently acquire raw data for multiple echoes at different echo times. A k-space row (k-space line) is thereby acquired (filled) multiple times for different echo times. Adjacent echoes are usually read out with opposite polarity of bipolar readout gradients. One requirement in such methods is that the different images must be consistent with one another, recognizing the fact that the readout points in time often exhibit a slight shift in the signal acquisition, this shift depending on the polarity of the gradient, i.e. on the direction in which entries of raw data are made into raw data space or k-space in the filling thereof with data. The different echoes are typically designated as even and odd echoes in a bipolar gradient echo sequence in order to indicate that these echoes are different and were not acquired with consistent shifts.

One possibility to construct such images is to reconstruct the individual images separately and then to combine the magnitude images. This has the disadvantage that only magnitude images can be calculated. Use of the phase information is not possible, for example as is necessary for the Dixon technique, for a B0 mapping, for a phase depiction, or for a depiction of the susceptibility, or for the flow coding by the phase or temperature imaging dependent on the chemical shift.

Two different possibilities are known for such a method. One possibility is to generate monopolar images in which it is ensured that all echoes in an MR image are even or all are odd, or that echoes of a defined echo time are all even or are all odd, wherein then only signals of even echoes are combined with signals of even echoes or signals of odd echoes are combined with odd echoes.

The first possibility—the monopolar approach—is not efficient with regard to the signal-to-noise ratio and the sequence workflow, and is also susceptible to eddy current effects. The second possibility—the bipolar method—limits the possible data for the processing. In particular if the first echo is even and the last echo is odd, or vice versa, it can be desirable to combine the MR signals of these two echoes since the greatest time period lies between the two echoes. However, this is not provided in the current possibilities.

### SUMMARY OF THE INVENTION

An object of the present invention is to at least partially overcome these disadvantages, and to provide possibilities to effectively combine even and odd echoes.

According to a first aspect of the present invention, a method is provided for the acquisition of MR signals, wherein the MR signals are gradient echoes. A first RF pulse is radiated, and multiple bipolar magnetic field gradients are switched (activated) to generate multiple first gradient echoes at different echo points in time after the radiation of the first RF pulse. Furthermore, the multiple first gradient echoes are acquired in multiple raw data sets, wherein a first line of the associated raw data set is filled with MR signals in each raw data set, wherein chronologically adjacent gradient echoes that occur after radiation of the first RF pulse are acquired with magnetic field gradients with opposite polarity. Furthermore, a second RF pulse is radiated, and multiple bipolar magnetic field gradients are switched to generate multiple second gradient echoes after the radiation of the second RF pulse. The multiple second gradient echoes are acquired in the multiple raw data sets, wherein in each raw data set the second line of the associated raw data set—which second line is situated adjacent to the first line of said associated raw data set—is filled with MR signals via switching of the multiple bipolar magnetic field gradients. Again, chronologically adjacent gradient echoes that occur after radiation of the second RF pulse are acquired with magnetic field gradients with opposite polarity. The multiple bipolar magnetic field gradients to generate the first and second gradient echoes are now switched such that, in each of the raw data sets, the first line of the associated raw data set and the adjacent second line in the opposite direction are filled with MR signals.

This can be repeated for the various lines or spokes of a raw data set until the respective raw data set is filled with raw data, wherein, in each raw data set, adjacent lines have respectively been filled with MR signals entered in opposite directions. With this unconventional filling of the raw data sets with raw data, in the subsequent image reconstruction it is possible to apply reconstruction techniques that are used in (designed for) parallel acquisition techniques wherein MR signals acquired simultaneously with multiple reception coils.

For each echo time, an associated raw data set is generated, and in each raw data set adjacent lines of the raw data set are filled with the signals in opposite directions. Raw data sets are therefore generated as noted above for the different echo times, wherein, for each echo time, a raw data set is present in which adjacent lines are filled with MR data in opposite directions.

After the readout of the multiple first gradient echoes and before the radiation of the second RF pulse, at least one magnetic field gradient to destroy any residual magnetization—known as a spoiler gradient—is preferably activated, in order to minimize the possibly present residual magnetization before the second signal acquisition.

The raw data sets of the different echo times can be supplied to an image reconstruction unit that is designed to generate MR images from MR signals that have been acquired simultaneously with at least two different reception coils. In the image reconstruction, the image reconstruction unit now generates a first coil raw data set from a respective raw data set from an echo, which first coil raw data set contains data from only the lines of the raw data set that have been filled with MR signals in one direction. The image reconstruction unit also generates a second coil raw data set that contains data from only the lines of the raw data set that have been filled with MR signals in the opposite direction. Thus, only even echoes or only odd echoes are now present in each coil raw data set. As mentioned above, these echoes differ by a slight shift depending on the polarity of the gradient that existed when the raw data of the respective echo were acquired. This slight time shifts between the even and odd echoes correspond, in the images, to different phase values. However, these different phase values also occur given parallel reconstruction techniques in which multiple coils receive the MR signals simultaneously. The two coil raw data sets are now supplied to the image reconstruction unit as if they were acquired by two different virtual coils. Since parallel reconstruction techniques with multiple coils are precisely matched to such a situation, they can operate with such data sets to generate an MR image from the two coil raw data sets. An image reconstruction unit can reconstruct an MR image from both coil raw data sets under the assumption that one of the two coil raw data sets was acquired by one of the at least two reception coils while the other coil raw data set was acquired by another of the at least two reception coils.

For the reconstruction of the MR images, the image reconstruction unit can reconstruct the lines that are missing in one of the two coil raw data sets using the lines used in the other coil raw data set. Furthermore, for thus coil-dependent calibration data can be used, wherein the respective missing lines in raw data space can be reconstructed with the coil-dependent calibration data.

The image reconstruction unit can reconstruct MR images from the coil raw data sets as it is known in the reconstruction of MR signals with parallel acquisition techniques such as GRAPPA, SENSE or SMASH.

However, in accordance with the invention, the different gradient echoes in a coil raw data set have not been acquired by multiple reception coils, but rather by only a single acquisition coil.

The invention furthermore concerns a magnetic resonance system that is designed to implement the method described above.

### BRIEF DESCRIPTION OF THE DRAWINGS

FIG. 1 schematically illustrates an MR system with which raw data sets can be acquired in which adjacent lines are respectively filled with MR signals in opposite directions.

FIG. 2 is a sequence diagram and the filling of raw data space with MR signals according to one aspect of the invention.

FIG. 3 is a flowchart for reconstruction of an MR image from the acquired raw data in accordance with the invention.

FIG. 4 is a flowchart of the basic steps with which MR images can be generated in which even and odd echoes can be combined arbitrarily in accordance with the invention.

### DESCRIPTION OF THE PREFERRED EMBODIMENTS

In the following, one possibility to generate raw data sets that are designed such that they can be supplied to the image reconstruction unit that constructs MRT images that have been acquired simultaneously by different coils is described with reference to the drawings.

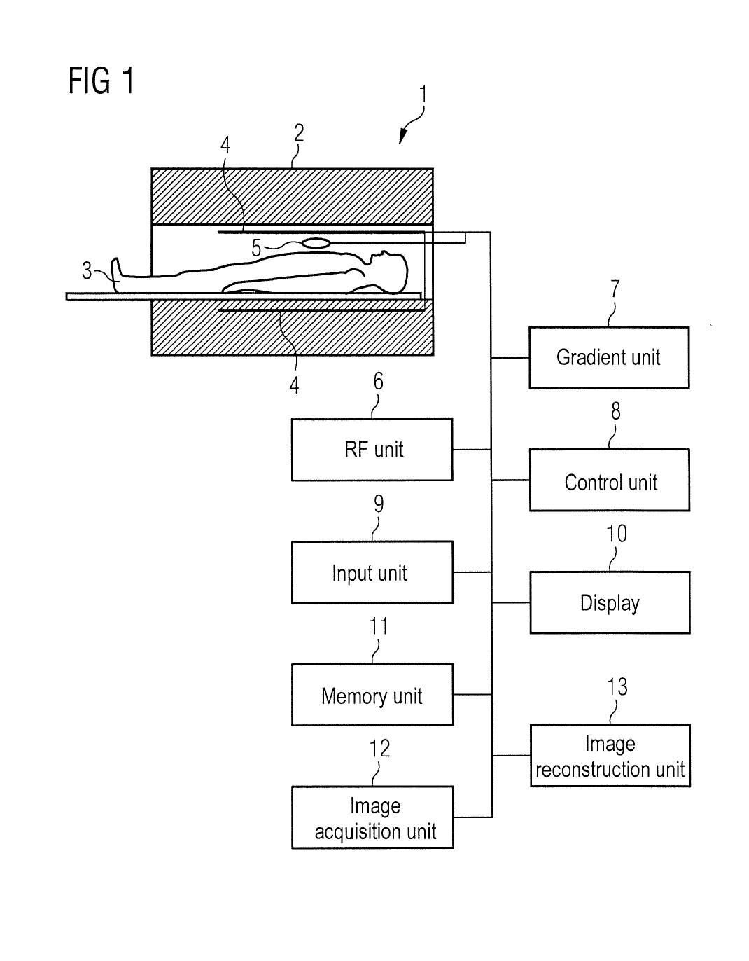

The MR system 1 shown in FIG. 1 has a magnet 2 that generates a polarization field BO to generate a polarization in a patient or the examined person 3. The MR system has gradient coils 4 to generate magnetic field gradients. A reception coil 5 detects the MR signals from the examined person. The reception coil 5 can also be used as a transmission coil, or a body coil (not shown) can be used to radiate RF pulses.

The RF pulses are generated by an RF unit 6, and the magnetic field gradients are generated by a gradient unit 7.

A central control unit 8 controls the MR system. An operator can input the desired information and control the MR system via an input unit 9. The MR images can be displayed at a display unit 10. For example, imaging sequences or other information can be stored in a memory unit 11. An image acquisition unit 12 is provided that establishes the sequence of RF pulses and magnetic field gradients depending on the desired imaging sequence, and that stores the MR signals detected by the coil 5 in raw data space to generate MR raw data that then form the basis for the reconstruction of an MR image. The image reconstruction takes place in an image reconstruction unit 13 that is designed to reconstruct an MR image with MR signals that were acquired simultaneously by different coils, for example with the GRAPPA, SENSE or SMASH technique.

The manner by which MR signals are detected using the sequence of RF pulses and magnetic field gradients, and how MR images are reconstructed in general, are known to those skilled in the art and need not be explained in detail herein.

Naturally, the MR system can have additional units that are not shown for clarity. Furthermore, the various units can be realized other than in the depicted separation of the individual units. It is possible that the different components are assembled into units or that different units are combined with one another. The units (depicted as functional units) can be designed as hardware, software or a combination of hardware and software.

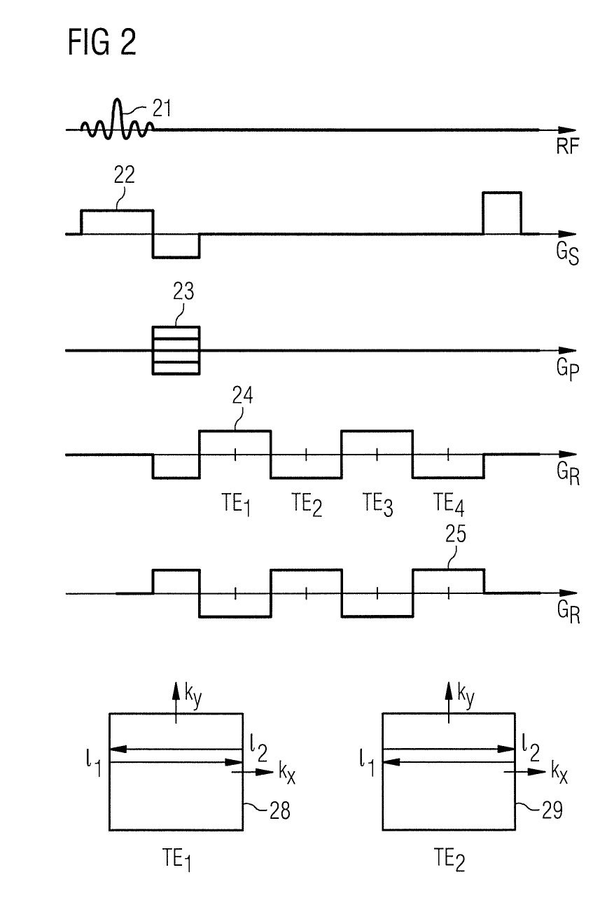

In FIG. 2, an imaging sequence is shown in which multiple MR images with different echo times can be generated. The shown imaging sequence is a gradient echoes in which an RF pulse 21 is radiated while a slice selection gradient 22 is switched to excite a slice. A phase coding gradient 23 is switched, wherein for each value of the phase coding gradient 23 multiple signal echoes are acquired by switching multiple bipolar readout gradients 24. As shown, from the switching of the gradient 24 a first echo is generated at the echo time TE1 at which the magnetic field gradient is positive during the readout, while the signal at the echo time TE2 has a negative readout gradient. Adjacent signals are acquired with a bipolar gradient of opposite polarity. This means that, for a phase coding gradient (La, for a k-space line), this is acquired multiple times at different echo times. The above scheme can now be repeated for another value of a phase coding gradient 23, but with the readout gradient 25. As is apparent there, the readout gradient 25 has an opposite polarity. If the echoes with positive readout gradient are now defined as even echoes and the echoes with negative readout gradient are defined as odd echoes, given the first signal readout the echoes TE1 and TE3 are even echoes and the echoes TE2 and TE4 are odd echoes. After the second excitation, the first and third echoes are odd and the second and fourth echoes are even. The phase coding gradient is now switched so that the respective adjacent k-space line in a raw data set has an opposite direction. “At the echo time TE1” means that a first k-space line L1 was read out in the positive direction (for example by the readout gradient 24) while the adjacent k-space line L2 was read out in the negative direction. At the second echo time, the same k-space line L1 was read out in the negative direction while the line L2 is read out in the positive direction. If this sequence is now repeated for different phase coding gradients until a desired filling of k-space is achieved, for each echo time a raw data set results in which adjacent lines respectively travel in opposite directions.

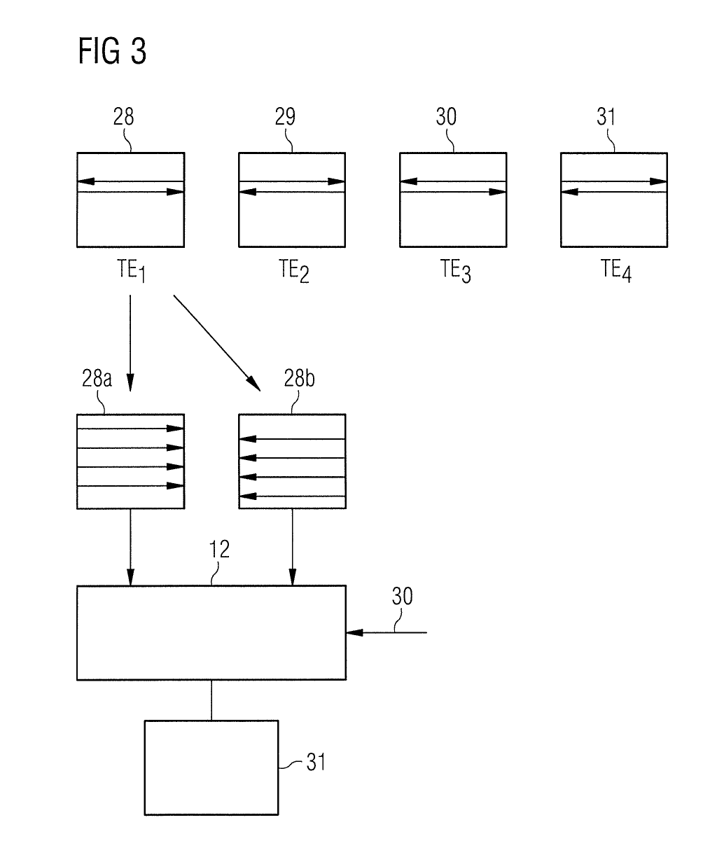

Referring also to FIG. 3, the four raw data sets are shown at the four different echo times, i.e. the raw data sets 28, 29, 30 and 31 for the echo time TE1-TE4. For the first raw data set 28, how an MR image is generated from this raw data set for the echo time TE is shown in the following as an example. From this raw data set, a coil raw data set 28a and a coil raw data set 28b are now generated. The coil raw data set 28a includes only the k-space lines that have been filled with MR signals in one direction while the coil raw data set 28b includes only raw data that have been filled with raw data in the opposite direction. This corresponds to two raw data sets in which—due to the different polarity in the signal generation—the two data sets respectively have a certain phase shift relative to one another due to the different polarity of the readout gradients. However, this is precisely the situation that exists for MR data that were acquired simultaneously with multiple coils. These two coil raw data sets are then supplied to the image reconstruction unit 13, wherein this image reconstruction unit 13 assumes that these data sets come from different coils, as is typically the case given parallel imaging. The image reconstruction unit 13 can then use image reconstruction techniques for reconstruction of the MR images, for example as they are known under the GRAPPA technique, SENSE technique, ITERATIVE SENSE or SMASH. The image reconstruction unit 13 can use calibration data of the different virtual coils (symbolized by the arrow 30). The calibration data set of a virtual coil can hereby be a data set that was acquired with the one reception coil that has only even or only odd echoes. Among other things, this has the advantage that the raw data space for the even and odd coil data sets does not need to be acquired for the same k-space lines in the event that the raw data space is filled 50% with even echoes and 50% with odd echoes, wherein the even and odd echoes alternative so that the entire image can be considered to be completely acquired. Given conventional parallel imaging, k-space is undersampled overall, meaning that some k-space lines are missing entirely. However, in the present invention the entirety of k-space is acquired (filled). One half is acquired with the one virtual coil and the other half is acquired with the second virtual coil. This is conventionally not possible/reasonable. So that the calibration data set is consistent with the data, this has only even/odd echoes for the respective virtual coil. In the reconstruction of the missing k-space lines in the coil raw data set 28a, the corresponding k-space lines of the data set 28b can be used, wherein these data are used in order to reconstruct the missing k-space lines in the coil raw data set 28a. Coil sensitivity data sets can hereby be used that—like the coil raw data set 28a—are generated from raw data that have signals that were read out in one direction, for example a data set with only even echoes around the center.

Such a method cancels the effect of the chemical shift and BO effects that would typically lead to opposite distortions in the images that were generated from even or odd echoes in that the data sets are combined.

The image reconstruction unit 13 can now generate from the two coil raw data sets 28a and 28b an MR image 31 that uses even and odd echoes. This can be implemented for all raw data sets 29 through 31.

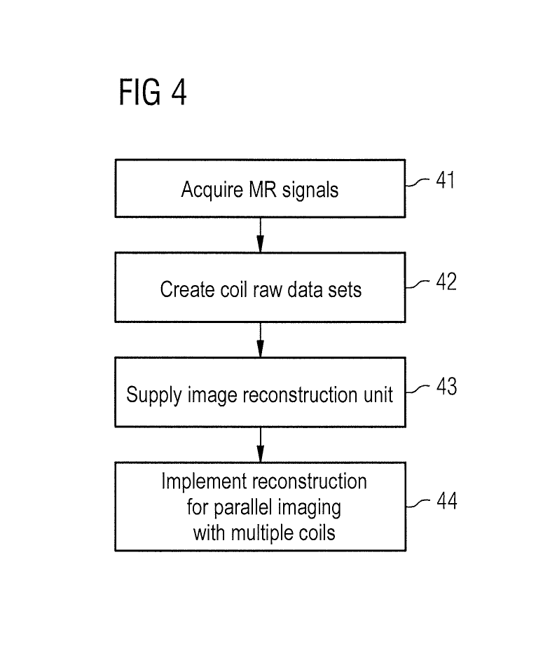

The steps are summarized in FIG. 4.

After acquisition of the signals in Step 41 (as was explained in detail in FIG. 2), in Step 42 the coil raw data sets are generated. In Step 41, the data sets are separated such that they come from different virtual coils, although this is not the case. Each virtual coil thereby includes the k-space lines that were acquired in one direction. In Step 43, these different coil raw data sets are supplied to the image acquisition unit, which is designed to reconstruct images that were acquired simultaneously by different reception coils. In Step 44, the reconstruction of the MR image in the image reconstruction unit takes place via parallel reconstruction methods such as GRAPPA, SENSE or the like.

The imaging sequence shown in FIG. 2 was described as a two-dimensional imaging sequence. Naturally, the method is also usable for 3D acquisition techniques. Furthermore, a Cartesian filling of the raw data space was used. Naturally, the invention is not limited to a Cartesian filling the raw data space. Other acquisition techniques—for example radial acquisition techniques—are also possible, wherein adjacent k-space lines travel in opposite directions.

Although modifications and changes may be suggested by those skilled in the art, it is the intention of the inventors to embody within the patent warranted hereon all changes and modifications as reasonably and properly come within the scope of their contribution to the art.

We claim as our invention:

1. A method to acquire magnetic resonance (MR) signals, comprising:
operating an MR data acquisition unit, in which a subject is situated, to radiate a first radio-frequency (RF) pulse and to activate multiple bipolar magnetic field gradients in order to excite nuclear spins in the subject and to generate multiple first gradient echoes, resulting from the excited nuclear spins, respectively at different echo times after radiation of the first RF pulse;
operating the MR data acquisition unit to acquire first gradient echoes respectively in multiple raw data sets and to enter the raw data sets via a processor into an electronic memory organized as k-space wherein, in each raw data set, a first line of a respective raw data set is filled with acquired raw data representing the first gradient echoes, with chronologically adjacent gradient echoes that occur after radiation of said first RF pulse being respectively acquired with opposite polarities of said bipolar magnetic field gradients;
operating the MR data acquisition unit to radiate a second RF pulse and to activate multiple bipolar magnetic field gradients to again excite nuclear spins in said subject and to generate multiple second gradient echoes, resulting from the again excited nuclear spins, after radiation of the second RF pulse;
operating the MR data acquisition unit to acquire the multiple second gradient echoes in said multiple raw data sets wherein, in each raw data set, a second line is filled with raw data representing the second gradient echoes, said second line being adjacent said first line in the respective raw data set, and wherein chronologically adjacent gradient echoes that occur after radiation of said second RF pulse are respectively acquired with opposite polarities of said magnetic field gradients;
operating said MR data acquisition unit to activate said multiple bipolar magnetic field gradients for generating said first and second gradient echoes so as to cause, in each of said multiple raw data sets, said first line and said adjacent second line to be filled with said raw data in opposite directions, and
making said multiple raw data sets in said electronic memory available at an output of said processor as a data file in a form for reconstructing an MR image of said subject from said data file.

2. A method as claimed in claim 1 comprising operating said MR data acquisition unit to generate a respective raw data set, in said multiple raw data sets, for each echo time, in which all adjacent lines of the respective raw data set are filled with raw data in opposite directions.

3. A method as claimed in claim 1 comprising operating said MR data acquisition unit to activate at least one magnetic field gradient, after acquiring said multiple first gradient echoes and before radiating said second RF pulse, to destroy residual magnetization of said nuclear spins in said subject.

4. A method as claimed in claim 1 comprising providing said data file to a computer and, in said computer, reconstructing said MR image of said subject from said multiple raw data sets in said data file, using an image reconstruction algorithm designed to generate an MR image from raw data acquired simultaneously with at least two different reception coils, and applying said image reconstruction algorithm to said multiple raw data sets in said data file by generating a first coil raw data set comprising only lines of a respective raw data set that were filled with raw data in one direction, and generating a second coil raw data set comprising only lines of a respective raw data set that were filled with raw data in an opposite direction.

5. A method as claimed in claim 4 comprising reconstructing said MR image in said computer by using said first coil raw data set and said second coil raw data set in said image reconstruction algorithm as if said first coil raw data set and said second coil raw data set were respectively acquired by at least two reception coils.

6. A method as claimed in claim 4 comprising, in said image reconstruction algorithm in said computer, reconstructing lines that are missing in one of said first or second coil raw data sets using lines from the other of said first and second coil raw data sets.

7. A method as claimed in claim 4 comprising employing, as said image reconstruction algorithm, an image reconstruction algorithm selected from the group consisting of GRAPPA, SENSE, and SMASH.

8. A method as claimed in claim 4 comprising, in said image reconstruction algorithm, generating coil-dependent calibration data and filling any lines of said first coil raw data set or said second coil raw data set that are missing with said coil-dependent calibration data.

9. A method as claimed in claim 1 comprising operating said MR data acquisition unit to acquire said multiple first gradient echoes and said multiple second gradient echoes with one reception coil of said MR data acquisition unit.

10. A magnetic resonance (MR) apparatus comprising:
an MR data acquisition unit, in which a subject is situated, said MR data acquisition unit comprising a radio frequency (RF) system and a gradient coil system;
an electronic memory;
a control unit configured to operate the MR data acquisition unit to radiate a first RF pulse with said RF system and to activate multiple bipolar magnetic field gradients with said gradient system, in order to excite nuclear spins in the subject and to generate multiple first gradient echoes, resulting from the excited nuclear spins, respectively at different echo times after radiation of the first RF pulse;
said control unit being configured to operate the MR data acquisition unit to acquire first gradient echoes respectively in multiple raw data sets and to enter the raw data sets into said electronic memory organized as k-space wherein, in each raw data set, a first line of a respective raw data set is filled with acquired raw data representing the first gradient echoes, with chronologically adjacent gradient echoes that occur after radiation of said first RF pulse being respectively acquired with opposite polarities of said bipolar magnetic field gradients;
said control unit being configured to operate the MR data acquisition unit to radiate a second RF pulse and to activate multiple bipolar magnetic field gradients to again excite nuclear spins in said subject and to generate multiple second gradient echoes, resulting from the again excited nuclear spins, after radiation of the second RF pulse;
said control unit being configured to operate the MR data acquisition unit to acquire the multiple second gradient echoes in said multiple raw data sets wherein, in each raw data set, a second line is filled with raw data representing the second gradient echoes, said second line being adjacent said first line in the respective raw data set, and wherein chronologically adjacent gradient echoes that occur after radiation of said second RF pulse are respectively acquired with opposite polarities of said magnetic field gradients;
said control unit being configured to operate said MR data acquisition unit to activate said multiple bipolar magnetic field gradients for generating said first and second gradient echoes so as to cause, in each of said multiple raw data sets, said first line and said adjacent second line to be filled with said raw data in opposite directions, and
said control unit being configured to make said multiple raw data sets in said electronic memory available at an output of said control unit as a data file in a form for reconstructing an MR image of said subject from said data file.
